(19) United States
(12) Patent Application Publication
(10) Pub. No.: US 2024/0146239 A1
(43) Pub. Date: May 2, 2024

(54) PHOTOVOLTAIC CONSTRUCTION

(71) Applicant: Dennis M. Danzik, Cody, WY (US)

(72) Inventor: Dennis M. Danzik, Cody, WY (US)

(21) Appl. No.: 18/500,591

(22) Filed: Nov. 2, 2023

Related U.S. Application Data
(60) Provisional application No. 63/382,077, filed on Nov. 2, 2022.

(51) Int. Cl. H02S 40/34; F21S 9/03; F21V 23/00

(52) U.S. Cl. CPC H02S 40/34; F21S 9/037; F21V 23/002; F21Y 2115/10

(57) ABSTRACT

Implementations of photovoltaic constructions may include a photovoltaic module having a plurality of photovoltaic cells and outgoing photovoltaic wiring directly coupled electrically and mechanically to the photovoltaic module. The outgoing photovoltaic wiring may include either a universal serial bus (USB) cable or a power over ethernet (PoE) cable. The USB cable or the PoE cable is configured to harvest power from the photovoltaic module.

### CROSS REFERENCE TO RELATED APPLICATIONS

This document claims the benefit of the filing date of U.S. Provisional Patent Application 63/382,077, entitled “Photovoltaic Light Fixture” to Dennis Danzik which was filed on Nov. 2, 2022, the disclosure of which is hereby incorporated entirely herein by reference.

### BACKGROUND

### 1. Technical Field

Aspects of this document relate generally to alternative energy. More specific implementations involve photovoltaic modules.

### 2. Background

Alternative energy sources are becoming increasingly important in view of the depletion of fossil fuel sources. Alternative energy sources may include light, wind, or hydropower sources. Photovoltaic modules capture light and convert it into electrical current.

### SUMMARY

Implementations of photovoltaic constructions may include a photovoltaic module having a plurality of photovoltaic cells and outgoing photovoltaic wiring directly coupled electrically and mechanically to the photovoltaic module. The outgoing photovoltaic wiring may include either a universal serial bus (USB) cable or a power over ethernet (PoE) cable. The USB cable or the PoE cable is configured to harvest power from the photovoltaic module.

Implementations of photovoltaic constructions may include one, all, or any of the following:

The outgoing photovoltaic wiring may include the USB cable.

The USB cable may harvest the power through only two of four conductors within the USB cable.

The USB cable may be configured to harvest between 1-71 watts through each conductor that harvests the power.

The outgoing photovoltaic wiring may include the PoE cable.

The PoE cable may harvest the power through only four of eight conductors within the PoE cable.

The PoE cable may be configured to harvest between 1-71 watts through each conductor that harvests the power.

Either the USB cable or the PoE cable may feed the power into one of a capacitor or a battery.

Implementations of a photovoltaic construction may include a back plate coupled over a first side of the photovoltaic module, a cover coupled over a second side of the photovoltaic module, and a plurality of magnets directly coupled to the back plate.

The photovoltaic module may be configured to couple within a light fixture.

Implementations of photovoltaic light fixtures may include a housing configured to receive a lightbulb and a photovoltaic construction having a photovoltaic module having a plurality of photovoltaic cells and outgoing photovoltaic wiring directly coupled electrically and mechanically to the photovoltaic module. The outgoing photovoltaic wiring may include either a universal serial bus (USB) cable or a power over ethernet (PoE) cable. The photovoltaic module may be configured to generate electricity using visible light emitted from the lightbulb. The USB cable or the PoE cable may be configured to harvest power from the photovoltaic module.

Implementations of photovoltaic light fixtures may include one, all, or any of the following:

The photovoltaic module may generate electricity when exposed to light having a wavelength between 380-750 nanometers.

The photovoltaic construction may include a second photovoltaic module.

The outgoing photovoltaic wiring may include the USB cable. The USB cable may harvest the power through only two of four conductors within the USB cable.

The outgoing photovoltaic wiring may include the PoE cable. The PoE cable may harvest the power through only four of eight conductors within the PoE cable.

The USB cable or PoE cable may be configured to harvest between 1-71 watts through each conductor that harvests the power in the USB cable or the PoE cable.

Implementations of photovoltaic light fixtures may include a housing having a plurality of sidewalls and a base, one or more bulb connectors coupled to the housing and configured to couple to a lightbulb, electrical wiring coupled to the one or more bulb connectors and configured to carry electrical current to the one or more bulb connectors, and a photovoltaic construction directly coupled to the base. The photovoltaic construction may include a photovoltaic module having a plurality of photovoltaic cells and outgoing photovoltaic wiring directly coupled electrically and mechanically to the photovoltaic module. The outgoing photovoltaic wiring may include either of a universal serial bus (USB) cable or a power over ethernet (PoE) cable. The photovoltaic module may be configured to generate electricity using visible light emitted from the lightbulb. The USB cable or the PoE cable may be configured to harvest power from the photovoltaic module. The USB cable or the PoE cable may be configured to feed the power to one of a battery or a capacitor.

Implementations of photovoltaic light fixtures may include one, all, or any of the following:

The housing may be configured to receive four linear light bulbs.

The lightbulb may be an LED lightbulb.

The USB cable or PoE cable may be configured to harvest between 1-71 watts through each conductor that is configured to harvest the power in either the USB cable or the PoE cable.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a break apart view of a photovoltaic construction;

FIG. 2 is a view of the cover side of the photovoltaic construction;

FIG. 3 is a side view of the photovoltaic construction;

FIG. 4 is a view of the backplate side of the photovoltaic construction;

FIG. 5 is a view of a universal serial bus (USB) connector;

FIG. 6 is a schematic of the USB connector of FIG. 5;

FIG. 7 is a view of a power-over-ethernet (PoE) connector;

FIG. 8 is a schematic of the PoE connector of FIG. 7;

FIG. 9 is a bottom perspective view of a photovoltaic light fixture;

FIG. 10 is a top perspective and partially exploded view of the light fixture of FIG. 9;

FIG. 11 is a bottom perspective and partially exploded view of FIG. 10;

FIG. 12 is a top perspective view of the photovoltaic light fixture of FIG. 9;

FIG. 13 is a partial view of the photovoltaic light fixture showing a cross-section of the photovoltaic light fixture;

FIG. 14 is a cross-sectional side view of a substantially cylindrical photovoltaic light fixture;

FIG. 15 is a bottom view of the photovoltaic light fixture of FIG. 14;

FIG. 16 is a cross-sectional side view of a frustoconical photovoltaic light fixture;

FIG. 17 is a bottom view of the photovoltaic light fixture of FIG. 16;

FIG. 18 is a cross-sectional side view of a photovoltaic light fixture having a single photovoltaic module; and

FIG. 19 is a cross-sectional side view of a photovoltaic light fixture having multiple photovoltaic modules.

### DESCRIPTION

This disclosure, its aspects and implementations, are not limited to the specific components, assembly procedures or method elements disclosed herein. Many additional components, assembly procedures and/or method elements known in the art consistent with the intended photovoltaic constructions and photovoltaic light structures will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such photovoltaic constructions and photovoltaic light fixtures, and implementing components and methods, consistent with the intended operation and methods.

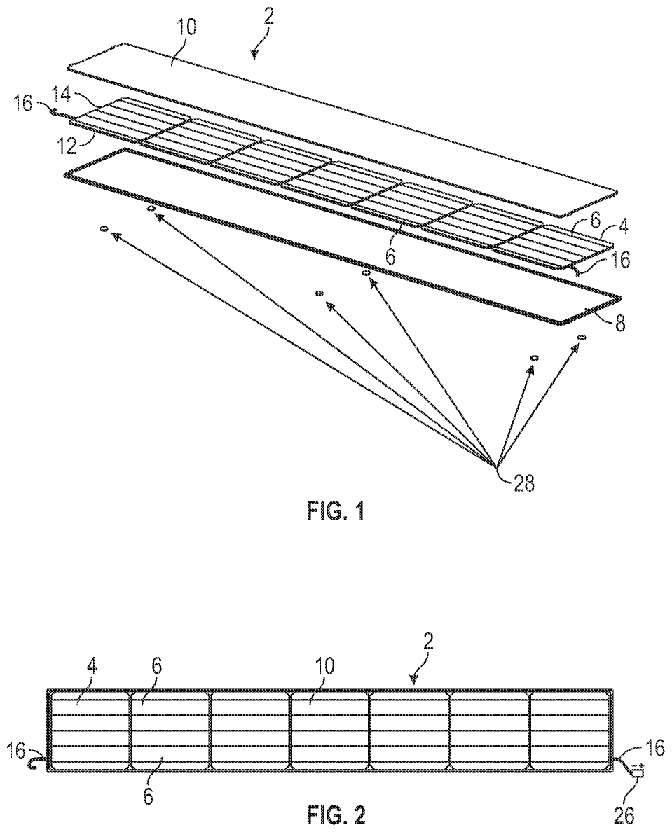

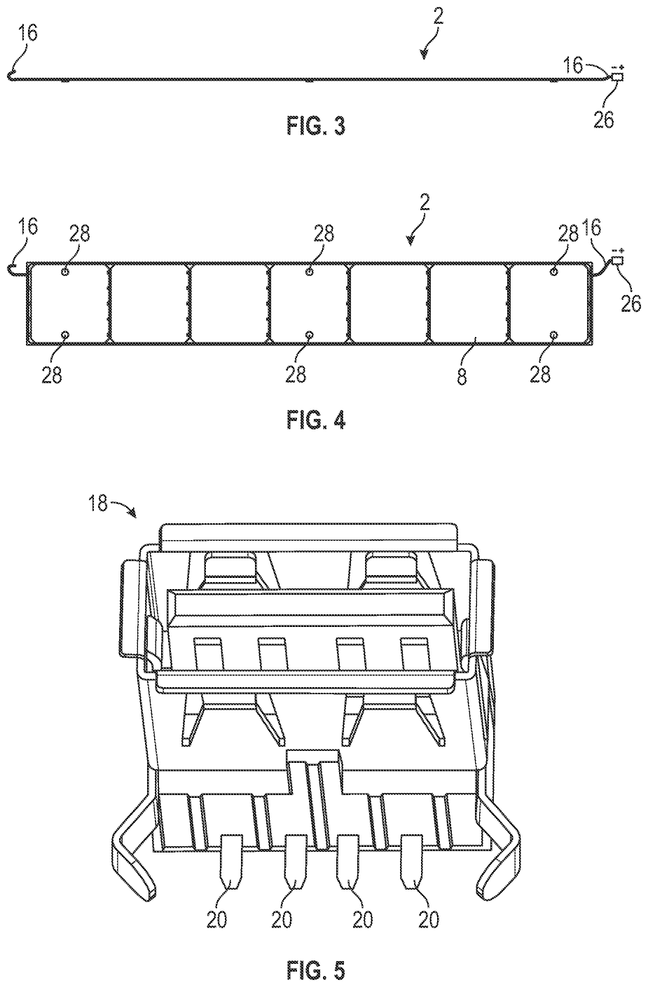

Referring to FIG. 1, a break apart view of a photovoltaic construction is illustrated. Referring to FIG. 2, a cover side of the photovoltaic construction is illustrated. Referring to FIG. 3, a side view of the photovoltaic construction is illustrated. Referring to FIG. 4, a backplate side of the photovoltaic construction is illustrated. The photovoltaic construction 2 includes a photovoltaic module 4 having a first side 12 and a second side 14. The photovoltaic module 4 includes a plurality of photovoltaic cells 6. As used herein, a plurality of photovoltaic cells make up a photovoltaic module and one or more photovoltaic modules make up a photovoltaic array. The photovoltaic module is configured to generate electricity or power in response to light hitting the photovoltaic module. The photovoltaic cells that generate the electricity or power may be made from, by nonlimiting example, polycrystalline silicon, amorphous silicon, dye-sensitized (flexible) silicon, other types of silicon, or other materials capable of producing electricity through the photovoltaic effect. In particular implementations, each photovoltaic cell is configured to generate electricity when exposed to light having a wavelength between 380 and 750 nm. In other implementations, the photovoltaic cells 6 may be configured to generate electricity when exposed to light having wavelength of less than 380 nm or more than 750 nm. The photovoltaic cells 6 may be optimized to generate more electricity from exposure to visible light than the standard photovoltaic cell included in a rooftop solar panel.

In various implementations the photovoltaic construction may include a single photovoltaic module. In other implementations the photovoltaic construction may include more than one photovoltaic module, including two, three, four, five, six, seven, eight or more than eight photovoltaic modules. In implementations having more than one photovoltaic module, the photovoltaic modules may lie in the same plane or may be angled relative to one another. Any of the photovoltaic modules of the photovoltaic construction may be planar. In other implementations, any of the photovoltaic modules of the photovoltaic construction may be curved.

In various implementations, the photovoltaic construction 2 may include a back plate 8 fixedly coupled to and over the first side 12 of the photovoltaic module. In other implementations, the photovoltaic module may not be coupled to a back plate but may be configured to mount directly to a surface configured to hold the photovoltaic construction. The back plate 8 may be made from, by nonlimiting example, metal, a polymer based material, or any other material having a rigidity sufficient to support the plurality of photovoltaic cells 6.

In various implementations, the photovoltaic construction includes a cover 10 coupled to and over the second side 14 of the photovoltaic module. The cover 10 is optically transmissive.

In implementations of photovoltaic constructions including multiple photovoltaic modules, the photovoltaic construction may include module wiring configured to couple the photovoltaic modules together. The multiple photovoltaic modules may be wired together in series or parallel. In particular implementations, the module wiring may include any type of USB cable or PoE cable disclosed herein.

The photovoltaic construction 2 includes outgoing photovoltaic wiring 16 directly coupled electrically and mechanically to the photovoltaic module 4. The outgoing photovoltaic wiring is configured to harvest the power from the photovoltaic module (or modules) and couples the photovoltaic module to a power receiving source, such as a capacitor or a battery. The outgoing photovoltaic modules may harvest the power in the form of direct current. FIGS. 1-4 illustrate two separate wires as part of the outgoing photovoltaic wiring 16. These two wires represent a wire configured to carry a positive charge and a wire configured to carry a negative charge. While these are illustrated on opposing ends of the photovoltaic module, the positive and/or negative charge may be routed so the channel configured to carry the positive charge and the channel configured to carry the negative charge extend from the photovoltaic module to a common cable.

In various implementations, the outgoing photovoltaic wiring includes a universal serial bus (USB) cable. The USB cable may be, by non-limiting example, a USB type A cable, a USB type B cable, a USB 3.0 cable, a USB mini cable, a USB micro cable, a USB type C cable, a USB micro B cable, or any other USB cable. In such implementations the USB cable harvests the power generated from the photovoltaic module. The USB cable can harvest the power because the USB cable may be directly wired (or soldered) to the positive and negative output of the photovoltaic module. The USB cable may also be directly wired (or soldered) to a positive wire or channel and a negative wire or channel directly coupled to the output of the photovoltaic module. In these implementations, the current from the photovoltaic module may be fed directly into the USB cable without first reaching any kind of controller, battery, capacitor, or switch. In similar implementations, a USB female connector may be directly wired (or soldered) to the output of the photovoltaic module or directly to a positive and negative wire or channel that is directly coupled to the output of the photovoltaic module. In such implementations, a USB cable may be plugged directly into the connector and the current from the photovoltaic module may be fed directly into the USB cable, through the connector, without first reaching any kind of controller, battery, capacitor, or switch. In either implementation, because the current from the photovoltaic module is transmitted directly into the USB cable or directly into the USB cable through the connector, the USB cable is considered to “harvest” the power generated.

In implementations including multiple photovoltaic modules, one or more USB female connectors may be directly wired (or soldered) to the output of each photovoltaic module. These connectors may allow for a plurality of USB cables to be used to wire the photovoltaic modules together. The photovoltaic modules may be wired in series or parallel. In other implementations, multiple photovoltaic modules may be wired together without the use of the USB female connectors.

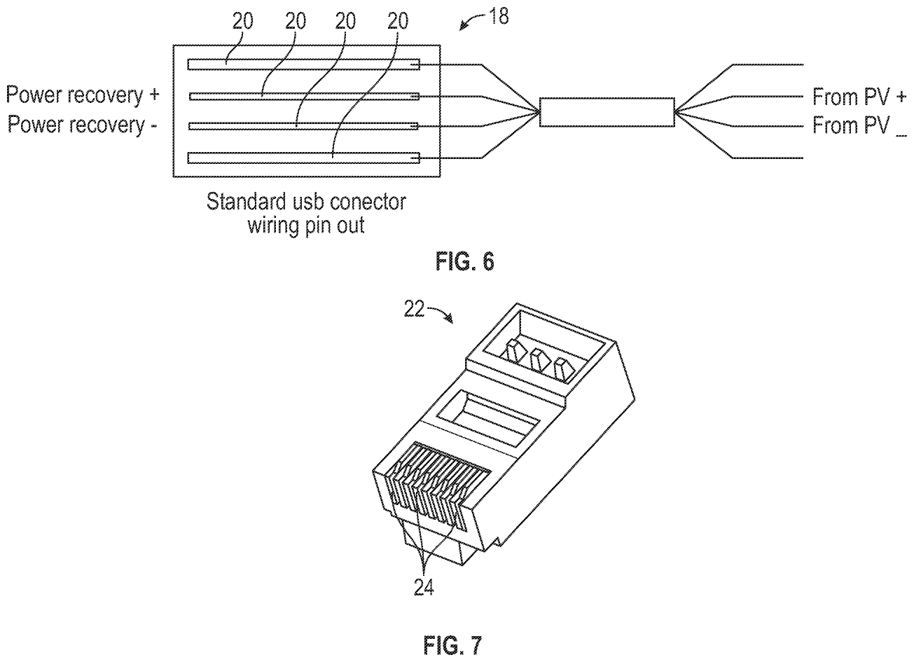

Referring to FIG. 5, a view of a USB connector is illustrated. Referring to FIG. 6, a schematic of the USB connector of FIG. 5 is illustrated. The USB connector 18 includes four terminals 20. These four terminals correspond to four conductors, or channels, that extend through the USB cable. In various implementations, the USB cable is configured to harvest power from the photovoltaic module through only two of the four conductors within the USB cable. In other implementations, the USB cable may be configured to harvest power through all four conductors. Each conductor that harvests power may harvest between 1-71 watts. In other implementations, each conductor within the USB cable that harvests power may be configured to harvest less than 1 watt or more than 71 watts.

In other implementations, the outgoing photovoltaic wiring includes a power-over-ethernet (PoE) cable. The PoE cable may be, by non-limiting example, a Cat-3 cable, a Cat-5 cable, a Cat-5e cable, a Cat-6 cable, a Cat-6a cable, a Cat-7 cable, Cat-8 cable, or any other type of PoE cable. In such implementations the PoE cable harvests the power generated from the photovoltaic module. The PoE cable harvests the power because the PoE cable may be directly wired (or soldered) to the output of the photovoltaic module. The PoE cable may also be directly wired (or soldered) to a positive wire or channel and a negative wire or channel directly coupled to the output of the photovoltaic module. In these implementations, the current from the photovoltaic module may be fed directly into the PoE cable without first reaching any kind of controller, injector, battery, capacitor, or switch. In similar implementations, a PoE female connector may be directly wired (or soldered) to the output of the photovoltaic module or directly wired (or soldered) to a positive and negative channel or wire directly coupled to the output of the photovoltaic module. In such implementations, a PoE cable may be plugged directly into the connector and the current from the photovoltaic module may be fed directly into the PoE cable, through the connector, without first reaching any kind of controller, injector, battery, capacitor, or switch. In either implementation, because the current from the photovoltaic module is transmitted directly into the PoE cable or directly into the PoE cable through the connector, the PoE cable is considered to “harvest” the power generated.

In implementations including multiple photovoltaic modules, one or more PoE female connectors may be directly wired (or soldered) to the output of each photovoltaic module. These connectors may allow for a plurality of PoE cables to be used to wire the photovoltaic modules together. The photovoltaic modules may be wired in series or parallel. In other implementations, multiple photovoltaic modules may be wired together without the use of the PoE female connectors.

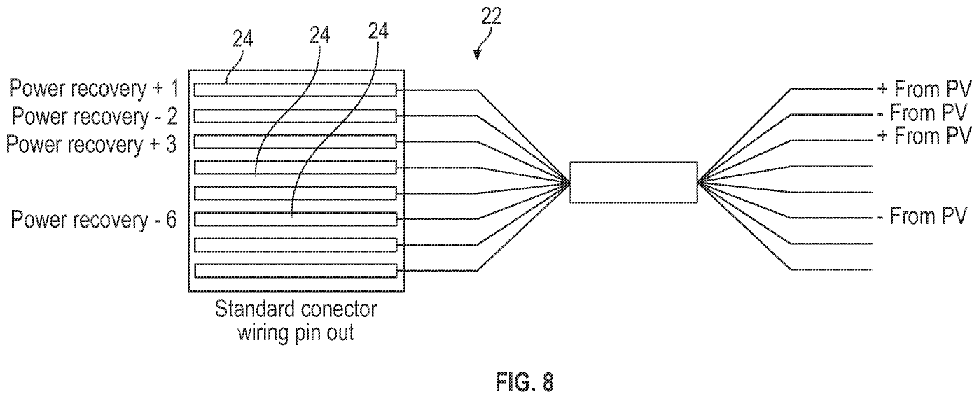

Referring to FIG. 7, a view of a PoE connector is illustrated. Referring to FIG. 8, a schematic of the PoE connector of FIG. 7 is illustrated. The PoE connector 22 includes eight terminals 24. These eight terminals correspond to eight conductors, or channels, that extend through the PoE cable. In various implementations, the PoE cable is configured to harvest power from the photovoltaic module through only four of the eight conductors within the PoE cable. In other implementations, the PoE cable may be configured to harvest power through all eight conductors, six conductors, or two conductors. Each conductor that harvests power may harvest between 1-71 watts (Cat-8 PoE cables may be configured to harvest up to 71 watts per conductor). In other implementations, each conductor within the PoE cable that harvests power may be configured to harvest less than 1 watt or more than 71 watts.

Either the USB cable or the PoE cable may be configured to feed the power harvested into either a capacitor or a battery. Either the USB cable or the PoE cable, depending on the particular implementation, forms the output of the outgoing photovoltaic wiring (i.e. additional elements that the USB cable or PoE cable may feed into are not considered part of the outgoing photovoltaic wiring). Referring to FIGS. 2-4, a battery 26 is illustrated with the outgoing photovoltaic wiring 16 coupled between the battery 26 and the photovoltaic module 4.

The photovoltaic construction 2 may include a plurality of attachment mechanisms 28, as illustrated by FIGS. 2-4. In implementations having a back plate 8, the attachment mechanisms 28 may be directly coupled to the back plate. In implementations not having a back plate, the attachment mechanisms 28 may be directly coupled to the photovoltaic module 4. In various implementations, the attachment mechanisms 28 may be magnets. In other implementations, the attachments mechanisms may include, by non-limiting example, an adhesive, clip, or other attachment mechanism.

Implementations of the photovoltaic construction 2 described herein may be configured to mount against various surfaces, including, by non-limiting example, to a wall, a floor, a ceiling, within a light fixture, to a piece of furniture, or to any other solid surface that receives light. In implementations where the photovoltaic construction is most responsive to visible light between 380-750 nm, the photovoltaic constructions may be used indoors to capture artificially generated light. The photovoltaic constructions may also be used outdoors to capture sunlight or reflected (ambient) sunlight. The artificially generated light may be emitted from low voltage light sources. Low voltage, as used herein, is less than 60 volts. In other implementations, the light through which the photovoltaic cells generate electricity may be greater than 60 volt sources.

In particular implementations the photovoltaic constructions may be included in photovoltaic light fixtures where they may generate power from light emitted from a lightbulb or other light source within the light fixture. In various implementations, the lightbulb or light source may be a low voltage light source.

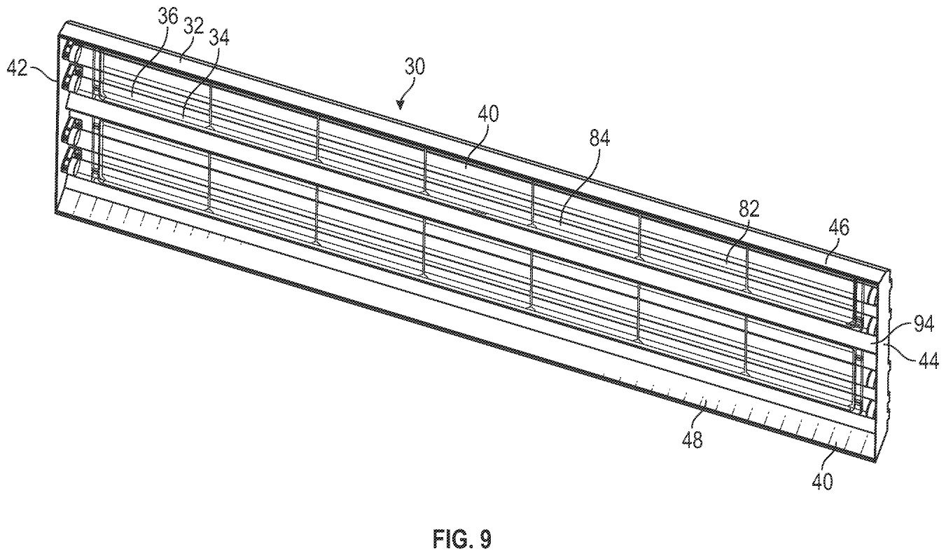

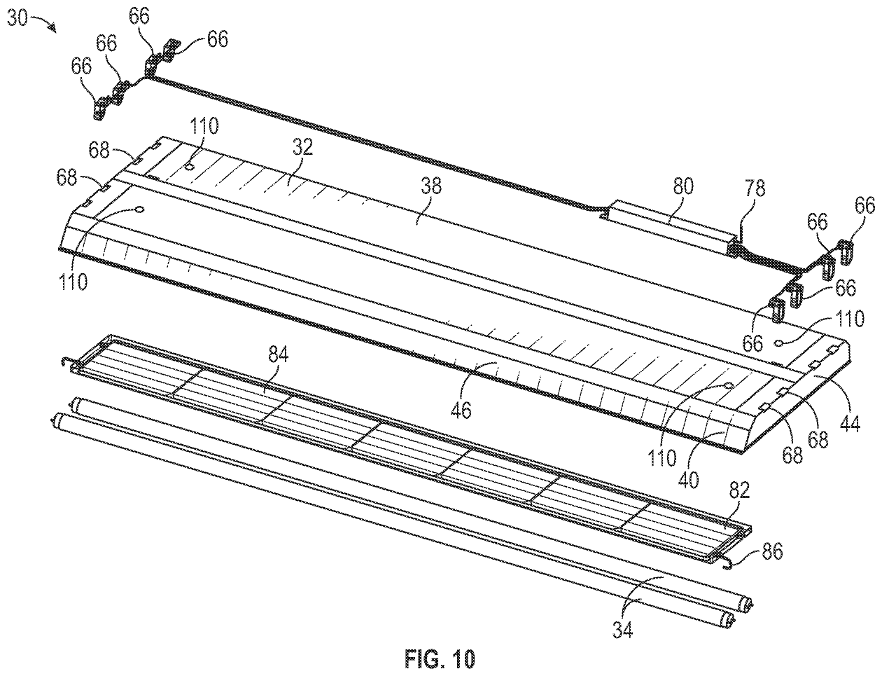

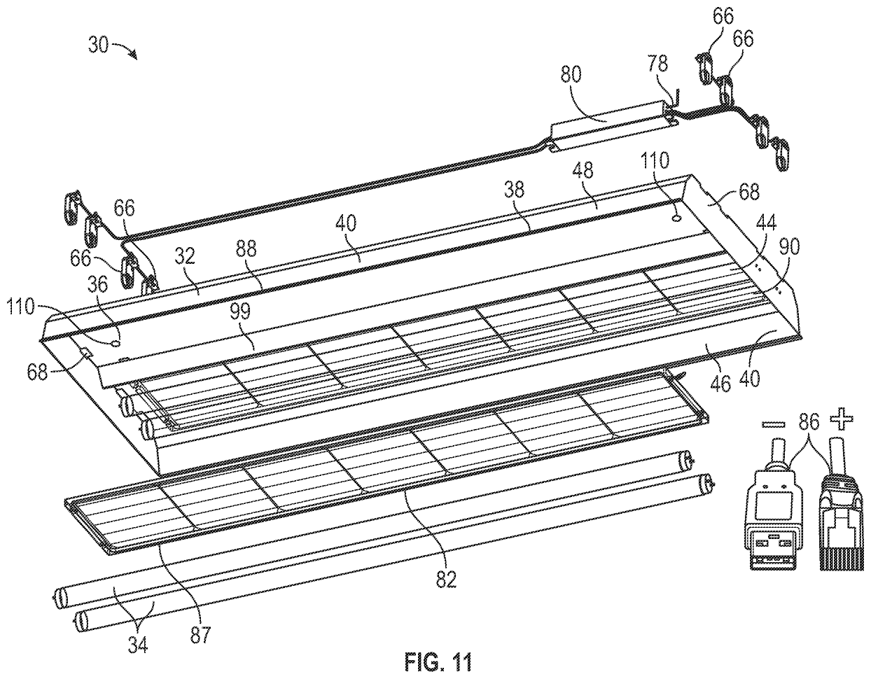

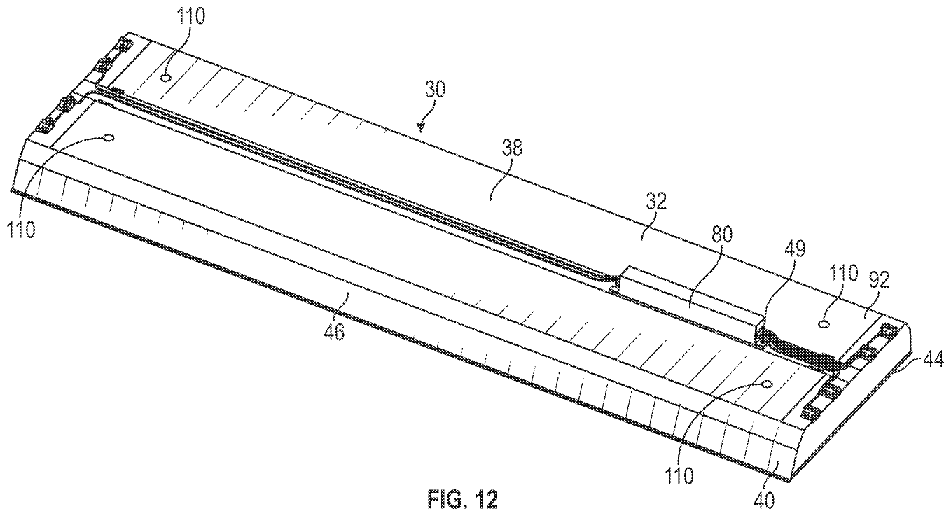

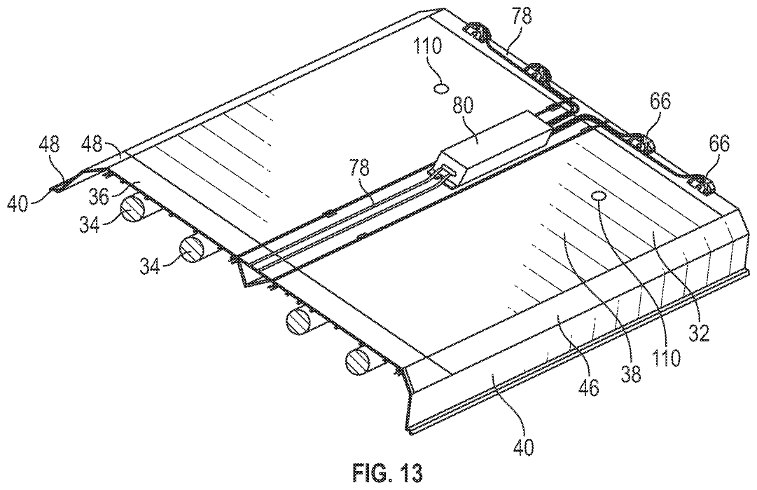

Referring to FIG. 9, a bottom view of a photovoltaic light fixture is illustrated. As used herein, “bottom” refers to the side of the photovoltaic light fixture having the opening through which light is emitted and “top” refers to the side opposite the bottom. Referring to FIG. 10, a top perspective and partially exploded view of the light fixture of FIG. 9 is illustrated. Referring to FIG. 11, a bottom perspective and partially exploded view of FIG. 10 is illustrated. Referring to FIG. 12, a top perspective view of the photovoltaic light fixture of FIG. 9 is illustrated. Referring to FIG. 13, a partial view of the photovoltaic light fixture of FIG. 12 showing a cross-section of the photovoltaic light fixture is illustrated. The views illustrated by FIGS. 10-11 are partially exploded as the figures only illustrate two of the four lightbulbs of FIGS. 4-6 and only one of the two photovoltaic modules of FIGS. 4-6 as exploded. While FIGS. 9-13 all illustrate a particular type of light fixture, it is understood that photovoltaic constructions may be included in any other type of light fixture configured to include any type of lightbulb. Further, it is understood that the shape of the photovoltaic constructions may be modified to fit a variety of different types of light fixtures.

Types of lightbulbs included in the photovoltaic light fixtures may include, by nonlimiting example, halogen, incandescent, florescent, sodium paper, carbon arc, light emitting diode (LED), or other visible light emitting lightbulbs. The shapes of lightbulbs may be, by nonlimiting example arbitrary, bulged, candle, globe, linear, tubular, bulged reflector, spiral, stick, spot, or any other type of shape of the lightbulb. In other implementations, rather than the light fixture including a lightbulb the light fixture may include a light emitting electronic device that is not a lightbulb.

In various implementations, any of the photovoltaic light fixtures disclosed herein may be configured to be coupled to or within a structure. In such implementations, the photovoltaic light fixture may be configured to be installed within a ceiling, wall, or floor of the structure. In other implementations, the photovoltaic light fixture may be configured to be installed within a work or laboratory bench. In still other implementations, the photovoltaic light fixture may be configured to attach to but not within the structure, such as photovoltaic light fixtures configured to hang from a ceiling. In still other implementations, the photovoltaic light fixture may be configured to be coupled to or within an automobile, streetlights, stadium lights, stand-alone spotlights, flashlights, or any other device or structure configured to emit light.

Implementations of the photovoltaic light fixtures disclosed herein may be configured to emit 100 lumens or less (such as a light fixture within a flashlight). In other implementations, photovoltaic light fixtures disclosed herein may be configured to emit more than 100 lumens of light and may be even configured to emit hundreds of thousands of lumens of light (such as the light fixtures used for stadium lighting).

Referring to FIGS. 9-13, the photovoltaic light fixture 30 includes a housing 32. The housing 32 may include a metallic material, such as sheet metal, a polymer based material, or any other type of material sufficiently rigid to form a light fixture housing. The housing 32 may include an interior 36 configured to receive one or more lightbulbs 34. In particular implementations, and as illustrated by FIGS. 9-13, the housing is configured to receive linear lightbulbs. In various implementations the housing may be configured to receive two or more linear lightbulbs. In particular implementations, the housing may be configured to receive four linear lightbulbs, a single lightbulb, or more than four lightbulbs. In particular implementations, the linear lightbulbs may be 4 feet long. In other implementations, the linear lightbulbs may be more than or less than 4 feet in length.

In various implementations, and as illustrated by FIGS. 10-13, the housing 32 includes a base 38. The base 38 is opposite an opening of the photovoltaic light fixture through which light is configured to pass. The base 38 may be substantially rectangular. In various implementations, the housing 32 includes a plurality of walls 40 directly coupled to the base 38. In particular implementations, and as illustrated by FIGS. 9-13, the housing may include a first wall 42, a second wall 44 opposite the first wall 42, a third wall 46, and a fourth wall 48 opposite the third wall 46. The third wall 46 and the fourth wall 48 may be coupled between the first wall 42 and the second wall 44. In various implementations, a portion of or all of the walls of the plurality of walls 40 may be substantially perpendicular to the surface of the base 38. In other implementations, a portion of the walls or all of the walls 40 may form a non-right angle with the base 38. In particular implementations, and as illustrated by FIGS. 9-13, the third wall 46 and the fourth wall 48 each include a portion that forms a non-right angle with the base 38. In various implementations, and as illustrated by FIGS. 9-13, the housing may substantially form the shape of a rectangular prism.

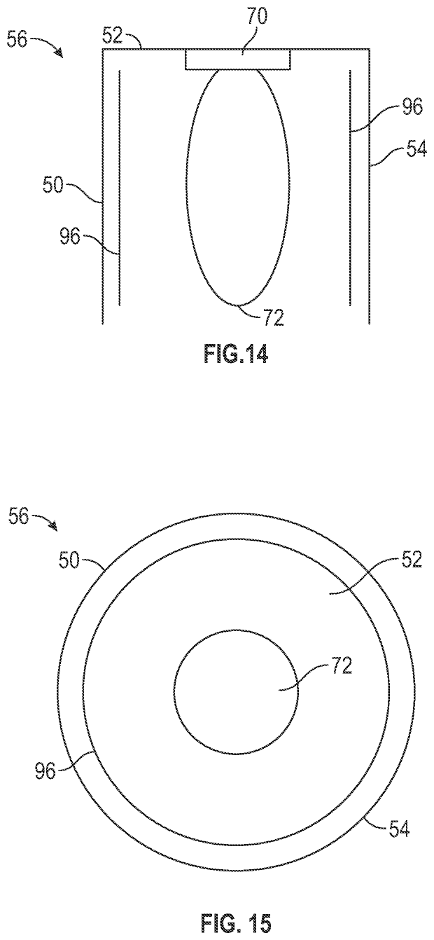

In other implementations, the housing of the photovoltaic light fixture may include a structure different from that illustrated by FIGS. 9-13. Referring to FIG. 14, a cross-sectional side view of a substantially cylindrical light fixture is illustrated. Referring to FIG. 15, a bottom view of the light fixture of FIG. 14 is illustrated. In various implementations, and as illustrated by FIGS. 14-15, the photovoltaic light fixture 56 includes a housing 50. The housing 50 may include a substantially circular base 52. In various implementations, the housing 50 may include a single curved sidewall 54 coupled around an outer perimeter of the base 52. In various implementations, the single curved sidewall 54 may be substantially perpendicular to the base 52 of the housing 50.

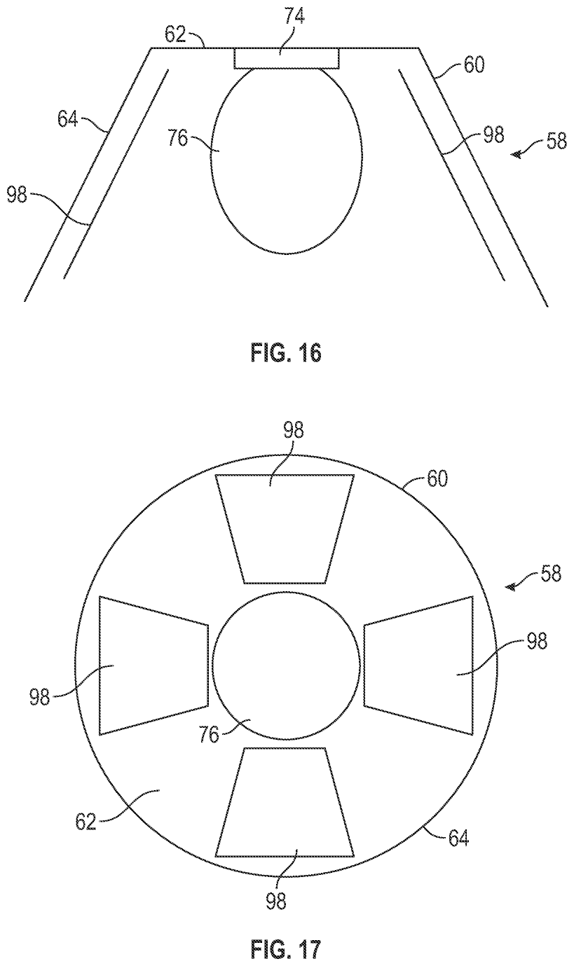

Referring to FIG. 16, a cross-sectional side view of a frustoconical light fixture is illustrated. Referring to FIG. 17, a bottom view of the light fixture of FIG. 16 is illustrated. In various implementations, and as illustrated by FIGS. 16-17, the photovoltaic light fixture 58 may include a housing 60 having a circular base 62. The housing 60 may include a single curved sidewall 64 coupled around an outer perimeter of the base 62. Differing from the structure of the light fixture illustrated by FIGS. 14-15, in various implementations the curved sidewall 64 may form a non-right angle with the base 62.

In other implementations, the photovoltaic light fixture may include a housing that includes a base without any walls. In still other implementations, implementations of the light fixtures disclosed herein may include housings the same as or similar to the housings of any other light fixture.

Implementations of the housings disclosed herein may be configured to house or couple to any type of lightbulb or device that emits light disclosed herein. Further, implementations of the housings disclosed herein may be configured to house or couple to a single lightbulb, two lightbulbs, three lightbulbs, four lightbulbs, or more than four lightbulbs.

In various implementations, and as illustrated by FIGS. 10-13, the housing includes one or more openings 110 through which the outgoing photovoltaic wiring extends. In various implementations, the openings may be next to the electrical outputs of the photovoltaic module. In such implementations, the outgoing photovoltaic wiring can be on the backside of the housing where it is hidden from view. The openings allow for the current from the photovoltaic module to be directly fed into the outgoing photovoltaic wiring which then passes through an opening to an outside of the light fixture. The outgoing photovoltaic wiring may then be hid from view. These openings may be used only for the outgoing photovoltaic wiring or may be shared between the outgoing photovoltaic wiring and other elements of the photovoltaic light fixture (such as, for example, a bulb connector). In other implementations, the housing may not include one or more openings for the outgoing photovoltaic wiring but the outgoing photovoltaic wiring may instead run over a wall of the housing towards a battery or capacitor.

Implementations of the light fixtures disclosed herein configured to receive a light bulb include one or more bulb connectors. The number of bulb connectors within the light fixture corresponds to the number of lightbulbs the light fixture is configured to hold. In various implementations, as illustrated by FIGS. 10-11, each bulb of the light bulbs 34 may be configured to directly couple to two different bulb connectors 66. In various implementations, the bulb connectors 66 may be directly coupled to the first wall 42, the second wall 44, the third wall 46, the fourth wall 48, the base 38, or any combination thereof. In various implementations, the base or walls may include a plurality of openings 68 corresponding to the number of bulb connectors included in the light fixture through which the bulb connectors 66 are configured to extend, thus allowing for wiring on the outside of the photovoltaic light fixture coupled to the bulb connectors.

In implementations of light fixtures configured to house non-linear lightbulbs, the light fixture may include a 1:1 ratio of bulb connectors and bulbs configured to be housed by the light fixture. For example, the photovoltaic light fixture 56 of FIGS. 14-15 includes a single bulb connector 70 configured to receive a single bulb 72. Similarly, the photovoltaic light fixture 58 of FIGS. 16-17 includes a single bulb connector 74 configured to receive a single bulb 76. In various implementations, these single bulb connectors of FIGS. 14-17 may be coupled directly to a sidewall or a base of the housing. In various implementations, the sidewall or the base may include an opening through which the bulb connectors are configured to extend. In such implementations, the opening through the housing allows wiring on the outside of housing to be directly coupled to the bulb connector.

In various implementations, and as illustrated by FIGS. 10-13, the photovoltaic light fixture 30 may include electrical wiring 78 configured to couple to an external power source and carry electrical current to the one or more bulb connectors. In particular implementations, as illustrated by FIGS. 10-13, the photovoltaic light fixture 30 may include a ballast 80 coupled between the electrical wiring 78 directly coupled to the bulb connectors 66 and electrical wiring 78 configured to transfer power from a power source to the photovoltaic light fixture 30. In other implementations, the light fixture may not include a ballast and the incoming wiring configured to transfer power from a power source to the light fixture may be directly coupled to the bulb connectors or light emitting devices.

Implementations of the photovoltaic light fixtures disclosed herein include a photovoltaic construction 82. The photovoltaic construction may be the same as or similar to any photovoltaic construction disclosed herein. More specifically, the photovoltaic construction within the photovoltaic light structure includes one or more photovoltaic modules 84 and outgoing photovoltaic wiring 86. The one or more photovoltaic modules 84 may be the same as or similar to any other photovoltaic module disclosed herein. The outgoing photovoltaic wiring 86 may be the same as or similar to any outgoing photovoltaic wiring disclosed herein. The photovoltaic modules 84 are configured to produce electricity from the visible light emitted by the one or more lightbulbs within the photovoltaic light fixture through the photovoltaic effect.

As illustrated by FIGS. 9-11 and 13, implementations of the photovoltaic light fixture 30 disclosed herein include one or more photovoltaic modules 84 coupled within the housing 32 between the housing and the bulb 34 or light source configured to be held by the light fixture. In various implementations, the one or more photovoltaic modules 84 lie along a base 38 or one or more walls 40 of the interior of the housing 32. In particular implementations, and as illustrated by FIGS. 9 and 11, the photovoltaic light fixture 30 may include a first photovoltaic module 86 over a first portion 88 of the base 38 and a second photovoltaic module 90 coupled over a second portion 92 of the base. The first and second portions of the base may be separated by a divider 94. While the photovoltaic light fixture of FIGS. 9-13 include two photovoltaic modules configured to generate electricity from the light emitted from four bulbs, other implementations of light fixtures may include additional photovoltaic modules coupled on the first wall, second wall, third wall, fourth wall, divider, or any combination thereof.

Referring to FIGS. 14-17, other examples of photovoltaic constructions are illustrated. While the illustrations of FIGS. 14-17 illustrate only the photovoltaic modules of the constructions, it is understood that these modules are coupled to outgoing photovoltaic wiring the same as or similar to any other outgoing photovoltaic wiring disclosed herein. FIGS. 14-17 illustrate photovoltaic modules coupled between a housing and a bulb within a fixture. Referring specifically to FIGS. 14-15, implementations of photovoltaic light fixtures having a cylindrical can housing may include a photovoltaic module 96 coupled to and parallel with the sidewall 54 of the housing 50. Referring to FIGS. 16-17, implementations of photovoltaic light fixtures having a frustoconical housing may include a plurality of photovoltaic modules 98 coupled against the interior of the housing 60. While the implementation of the light fixture of FIGS. 16-17 illustrate four different photovoltaic modules, in other implementations the four photovoltaic modules may be replaced by a single curved photovoltaic module that extends around an entire circumference of a lightbulb within the light housing, two photovoltaic modules, three photovoltaic modules, or more than four photovoltaic modules.

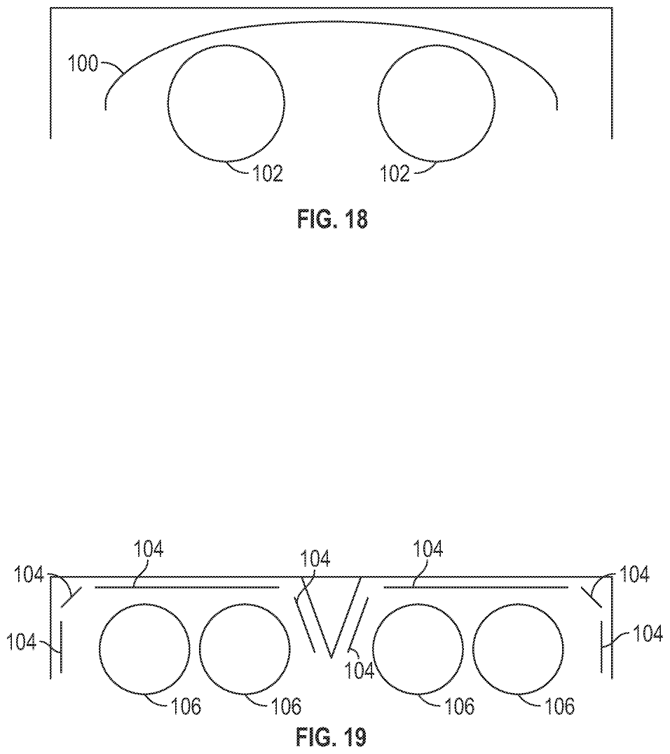

Referring to FIG. 18, a cross-sectional side view of a light fixture having a single photovoltaic module is illustrated. In various implementations, any of the photovoltaic modules disclosed herein may be curved. In such implementations, the curvature of the photovoltaic module 100 may correspond with the curvature of one or more lightbulbs 102 to receive the light emitted from the bulb more directly as illustrated by FIG. 18. Referring to FIG. 19, a cross-sectional side view of the light fixture having multiple photovoltaic modules is illustrated. In various implementations, the one or more photovoltaic modules 104 may be planar but may also be angled to receive light emitted from the one or more bulbs 106 more directly as illustrated by FIG. 19.

In the various implementations disclosed herein, the major surface of the one or more photovoltaic modules facing the housing may correspond with, or be substantially parallel to, the surface of the housing facing the corresponding photovoltaic module. In other implementations, the major surface of the one or more photovoltaic modules facing the housing may not be parallel to, or correspond with, the surface of the housing facing the corresponding photovoltaic module.

In the implementations of photovoltaic light fixtures disclosed herein, the photovoltaic constructions may not block visible light from exiting through the opening of the housing illuminating the surrounding area. In such implementations, the photovoltaic light fixtures allows for the collection of visible light from the bulb or electrical device so that a photovoltaic effect of the light produced can generate electricity while still allowing the light fixture to illuminate the intended and surrounding area.

The photovoltaic light fixtures disclosed herein include one or more attachment mechanisms used to secure the one or more photovoltaic modules to the housing (such as, by non-limiting example, the attachment mechanisms 28 of FIG. 1). By nonlimiting example, the attachment mechanism may include an adhesive, clip, magnets, a welded joint, or a shelf built into or attached to the housing that is configured to hold the one or more photovoltaic modules. In other implementations, the attachment mechanism may include any other type of attachment mechanism.

In various implementations, and depending upon the bulb used in the light fixture, the light fixtures may be configured to maintain a temperature, or not heat up from the light bulb used therein (such as would be the case with LED bulbs). In such implementations, the longevity of the photovoltaic modules may be increased inasmuch as the photovoltaic modules do not have to withstand elevated temperatures from the light striking the photovoltaic modules.

Implementations of the photovoltaic light fixtures disclosed herein all generate electricity from otherwise wasted photons that strike and/or are absorbed by the interior of a light fixture. Further, the implementations of photovoltaic light fixtures disclosed herein are safe inasmuch as the photovoltaic modules are within the housing and are not typically positioned in a location that is readily accessible by people or animals. Further, the photovoltaic modules of the photovoltaic constructions disclosed herein are also housed and protected by the housing, thus further increasing the longevity of the photovoltaic modules within the light fixture.

In places where the description above refers to particular implementations of photovoltaic constructions and photovoltaic light fixtures, and implementing components, sub-components, methods and sub-methods, it should be readily apparent that a number of modifications may be made without departing from the spirit thereof and that these implementations, implementing components, sub-components, methods and sub-methods may be applied to other photovoltaic constructions and photovoltaic light fixtures.

What is claimed is:

1. A photovoltaic construction comprising:
a photovoltaic module comprising a plurality of photovoltaic cells; and
outgoing photovoltaic wiring directly coupled electrically and mechanically to the photovoltaic module;
wherein the outgoing photovoltaic wiring comprises one of a universal serial bus (USB) cable or a power over ethernet (PoE) cable;
wherein the one of the USB cable or the PoE cable is configured to harvest power from the photovoltaic module.

2. The photovoltaic construction of claim 1, wherein the outgoing photovoltaic wiring comprises the USB cable.

3. The photovoltaic construction of claim 2, wherein the USB cable is configured to harvest the power through only two of four conductors within the USB cable.

4. The photovoltaic construction of claim 3, wherein the USB cable is configured to harvest between 1-71 watts through each conductor that harvests the power.

5. The photovoltaic construction of claim 1, wherein the outgoing photovoltaic wiring comprises the PoE cable.

6. The photovoltaic construction of claim 5, wherein the PoE cable is configured to harvest the power through only four of eight conductors within the PoE cable.

7. The photovoltaic construction of claim 6, wherein the PoE cable is configured to harvest between 1-71 watts through each conductor that harvests the power.

8. The photovoltaic construction of claim 1, wherein the one of the USB cable or the PoE cable feeds the power into one of a capacitor or a battery.

9. The photovoltaic construction of claim 1, further comprising a back plate coupled over a first side of the photovoltaic module, a cover coupled over a second side of the photovoltaic module, and a plurality of magnets directly coupled to the back plate.

10. The photovoltaic construction of claim 1, wherein the photovoltaic module is configured to couple within a light fixture.

11. A photovoltaic light fixture comprising:
a housing configured to receive a lightbulb; and
a photovoltaic construction comprising a photovoltaic module comprising a plurality of photovoltaic cells and outgoing photovoltaic wiring directly coupled electrically and mechanically to the photovoltaic module;
wherein the outgoing photovoltaic wiring comprises one of a universal serial bus (USB) cable or a power over ethernet (PoE) cable;
wherein the photovoltaic module is configured to generate electricity using visible light emitted from the lightbulb;
wherein the one of the USB cable or the PoE cable is configured to harvest power from the photovoltaic module.

12. The photovoltaic light fixture of claim 11, wherein the photovoltaic module generates electricity when exposed to light having a wavelength between 380-750 nanometers.

13. The photovoltaic light fixture of claim 11, wherein the photovoltaic construction further comprises a second photovoltaic module.

14. The photovoltaic light fixture of claim 11, wherein the outgoing photovoltaic wiring comprises the USB cable and wherein the USB cable is configured to harvest the power through only two of four conductors within the USB cable.

15. The photovoltaic light fixture of claim 11, wherein the outgoing photovoltaic wiring comprises the PoE cable and wherein the PoE cable is configured to harvest the power through only four of eight conductors within the PoE cable.

16. The photovoltaic light fixture of claim 11, wherein the one of the USB cable or PoE cable is configured to harvest between 1-71 watts through each conductor that is configured to harvest the power in the one of the USB cable or the PoE cable.

17. A photovoltaic light fixture comprising:
a housing comprising a plurality of sidewalls and a base;
one or more bulb connectors coupled to the housing and configured to couple to a lightbulb;
electrical wiring coupled to the one or more bulb connectors and configured to carry electrical current to the one or more bulb connectors; and
a photovoltaic construction directly coupled to the base, the photovoltaic construction comprising a photovoltaic module comprising a plurality of photovoltaic cells and outgoing photovoltaic wiring directly coupled electrically and mechanically to the photovoltaic module;
wherein the outgoing photovoltaic wiring comprises one of a universal serial bus (USB) cable or a power over ethernet (PoE) cable;
wherein the photovoltaic module is configured to generate electricity using visible light emitted from the lightbulb;
wherein the one of the USB cable or the PoE cable is configured to harvest power from the photovoltaic module; and
wherein the one of the USB cable or the PoE cable is configured to feed the power to one of a battery or a capacitor.

18. The photovoltaic light fixture of claim 17, wherein the housing is configured to receive four linear light bulbs.

19. The photovoltaic light fixture of claim 17, wherein the lightbulb is an LED lightbulb.

20. The photovoltaic light fixture of claim 17, wherein the one of the USB cable or PoE cable is configured to harvest between 1-71 watts through each conductor that is configured to harvest the power in the one of the USB cable or the PoE cable.
